(19) United States
(12) Patent Application Publication
(10) Pub. No.: US 2025/0111104 A1
(43) Pub. Date: Apr. 3, 2025

(54) INFORMATION PROCESSING APPARATUS, INFORMATION PROCESSING METHOD, AND INFORMATION PROCESSING PROGRAM

(71) Applicant: FUJIFILM CORPORATION, Tokyo (JP)

(72) Inventors: Takuya OSUGI, Kanagawa (JP); Yuki MATSUMOTO, Kanagawa (JP); Masashi SATO, Kanagawa (JP); Hiroshi YONEKUBO, Kanagawa (JP)

(21) Appl. No.: 18/977,940

(22) Filed: Dec. 12, 2024

Related U.S. Application Data
(63) Continuation of application No. PCT/JP2023/013734, filed on Mar. 31, 2023.

(30) Foreign Application Priority Data
Jul. 19, 2022 (JP) 2022-115039

(51) Int. Cl. G06F 30/20

(52) U.S. Cl. CPC G06F 30/20

(57) ABSTRACT

An information processing apparatus selects an excluded element set that is a subset of a tentative element set, from the tentative element set that is at least a part of a solution target element set constituting an optimization problem as a solution target, determines whether or not a tentative mathematical model that is a mathematical model in which an element set excluding the excluded element set from the tentative element set and a constraint condition are formulated, is feasible, in a case where the tentative mathematical model is determined to be infeasible, extracts a list of constraint conditions conflicting with each other from the tentative mathematical model, converts each constraint condition of the extracted list into a name of the constraint condition, and outputs the name of the constraint condition obtained by conversion.

### CROSS-REFERENCE TO RELATED APPLICATIONS

This application is a continuation application of International Application No. PCT/JP2023/013734, filed Mar. 31, 2023, the disclosure of which is incorporated herein by reference in its entirety. Further, this application claims priority from Japanese Patent Application No. 2022-115039, filed Jul. 19, 2022, the disclosure of which is incorporated herein by reference in its entirety.

### BACKGROUND

### 1. Technical Field

The present disclosure relates to an information processing apparatus, an information processing method, and an information processing program.

### 2. Related Art

WO2021/251001A1 discloses a technology for selecting a tentative task group that is a partial task group, from a calculation target task group including a plurality of tasks as a scheduling target, and performing processing of deriving a feasible schedule that is a feasible schedule plan in which the selected tentative task group satisfies a constraint condition. In this technology, in a case where a result of the processing indicates that the feasible schedule is not present, the calculation target task group is replaced with the tentative task group. In a case where the number of tasks in the calculation target task group is one, the calculation target task group is specified as a cause task causing inability to perform scheduling. Furthermore, in this technology, in a case where the number of tasks in the calculation target task group is two or more, selection of the tentative task group and derivation of the feasible schedule are executed again, and processing of specifying a cause constraint condition that is a constraint condition causing inability to execute the cause task is executed.

### SUMMARY

In solving an optimization problem via a computer, a constraint condition for solving the optimization problem is in a form (for example, a mathematical expression) interpretable by the computer. Accordingly, in a case where a feasible solution of the optimization problem cannot be obtained, it is difficult for a user to understand a cause of inability to obtain the feasible solution even in a case where the computer specifies a constraint condition causing the inability to obtain the feasible solution and presents the specified constraint condition to the user.

The present disclosure has been conceived in view of the above circumstances, and an object of the present disclosure is to provide an information processing apparatus, an information processing method, and an information processing program that can present a cause of inability to obtain a feasible solution in an optimization problem in a form understandable by a user.

According to a first aspect, there is provided an information processing apparatus comprising at least one processor, in which the processor is configured to select an excluded clement set that is a subset of a tentative element set, from the tentative element set that is at least a part of a solution target element set which is an element set constituting an optimization problem as a solution target and which is composed of a plurality of elements, determine whether or not a tentative mathematical model that is a mathematical model in which an element set excluding the excluded element set from the tentative element set and a constraint condition are formulated, is feasible, in a case where the tentative mathematical model is determined to be infeasible, extract a list of constraint conditions conflicting with each other from the tentative mathematical model, convert each constraint condition of the extracted list into a name of the constraint condition, and output the name of the constraint condition obtained by conversion.

According to a second aspect of the information processing apparatus, in the information processing apparatus of the first aspect, the processor is configured to execute processing of determining whether or not the tentative mathematical model is feasible a plurality of times while changing the excluded element set, and further output the excluded clement set and a feasible solution in a case where the tentative mathematical model is determined to be feasible, in a form set in accordance with the optimization problem.

According to a third aspect of the information processing apparatus, in the information processing apparatus according to the second aspect, the processor is configured to, in a case where the tentative mathematical model is determined to be feasible at least once, and the tentative mathematical model is determined to be infeasible at least once, extract a list of constraint conditions conflicting with each other from the tentative mathematical model determined to be infeasible.

According to a fourth aspect of the information processing apparatus, in the information processing apparatus according to the second or third aspect, the processor is configured to repeat executing, until a predetermined condition is satisfied, processing of selecting the excluded element set from the tentative element set, processing of determining whether or not the tentative mathematical model is feasible, processing of, in a case where the tentative mathematical model is determined to be feasible, adding 1 to the number of times the tentative mathematical model is determined to be feasible, and processing of, in a case where the tentative mathematical model is determined to be infeasible, setting the element set excluding the excluded element set from the tentative element set used in formulating the tentative mathematical model, as the tentative element set.

According to a fifth aspect of the information processing apparatus, in the information processing apparatus according to the fourth aspect, the predetermined condition is a condition that the number of consecutive times the tentative mathematical model is determined to be feasible is greater than or equal to a threshold value.

According to a sixth aspect, there is provided an information processing method executed by a processor included in an information processing apparatus, the method comprising selecting an excluded element set that is a subset of a tentative element set, from the tentative element set that is at least a part of a solution target element set which is an element set constituting an optimization problem as a solution target and which is composed of a plurality of elements, determining whether or not a tentative mathematical model that is a mathematical model in which an element set excluding the excluded element set from the tentative element set and a constraint condition are formulated, is feasible, extracting, in a case where the tentative mathematical model is determined to be infeasible, a list of constraint conditions conflicting with each other from the tentative mathematical model, converting each constraint condition of the extracted list into a name of the constraint condition, and outputting the name of the constraint condition obtained by conversion.

According to a seventh aspect, there is provided an information processing program causing a processor included in an information processing apparatus to execute a process comprising selecting an excluded element set that is a subset of a tentative element set, from the tentative element set that is at least a part of a solution target element set which is an element set constituting an optimization problem as a solution target and which is composed of a plurality of elements, determining whether or not a tentative mathematical model that is a mathematical model in which an element set excluding the excluded element set from the tentative element set and a constraint condition are formulated, is feasible, extracting, in a case where the tentative mathematical model is determined to be infeasible, a list of constraint conditions conflicting with each other from the tentative mathematical model, converting each constraint condition of the extracted list into a name of the constraint condition, and outputting the name of the constraint condition obtained by conversion.

According to the present disclosure, a cause of inability to obtain a feasible solution in an optimization problem can be presented in a form understandable by a user.

### BRIEF DESCRIPTION OF THE DRAWINGS

Exemplary embodiments according to the technique of the present disclosure will be described in detail based on the following figures, wherein:

FIG. 1 is a block diagram illustrating an example of a hardware configuration of an information processing apparatus;

FIG. 2 is a block diagram illustrating an example of a functional configuration of the information processing apparatus;

FIG. 3 is a flowchart illustrating an example of cause presentation processing;

FIG. 4 is a diagram for describing transitions of a tentative element set and an excluded element set in a case where a determination indicating feasibility is made;

FIG. 5 is a diagram for describing transitions of the tentative element set and the excluded element set in a case where a determination indicating infeasibility is made;

FIG. 6 is a diagram illustrating an example of product type data;

FIG. 7 is a diagram illustrating an example of operator data;

FIG. 8 is a diagram illustrating an example of operation order data;

FIG. 9 is a diagram illustrating an example of data related to skill of an operator;

FIG. 10 is a diagram illustrating an example of a correspondence relationship between a task and a combination of a product type and an operation;

FIG. 11 is a diagram for describing whether or not a constraint condition is presentable to a user according to a first example;

FIG. 12 is a diagram illustrating an example of a look-up table in which the constraint condition and a name of the constraint condition are associated with each other according to the first example;

FIG. 13 is a diagram illustrating an example of a presentation screen for the user according to the first example;

FIG. 14 is a diagram for describing an optimization problem according to a second example;

FIG. 15 is a diagram illustrating an example of load data;

FIG. 16 is a diagram illustrating an example of truck data;

FIG. 17 is a diagram for describing whether or not the constraint condition is presentable to the user according to the second example;

FIG. 18 is a diagram illustrating an example of the look-up table in which the constraint condition and the name of the constraint condition are associated with each other according to the second example;

FIG. 19 is a diagram illustrating an example of the presentation screen for the user according to the second example;

FIG. 20 is a diagram for describing an optimization problem according to a third example;

FIG. 21 is a diagram illustrating an example of transportation task data;

FIG. 22 is a diagram illustrating an example of moving time data;

FIG. 23 is a diagram illustrating an example of operator information;

FIG. 24 is a diagram for describing whether or not the constraint condition is presentable to the user according to the third example;

FIG. 25 is a diagram illustrating an example of the look-up table in which the constraint condition and the name of the constraint condition are associated with each other according to the third example; and

FIG. 26 is a diagram illustrating an example of the presentation screen for the user according to the third example.

### DETAILED DESCRIPTION

Hereinafter, examples for embodying the disclosed technology will be described in detail with reference to the drawings.

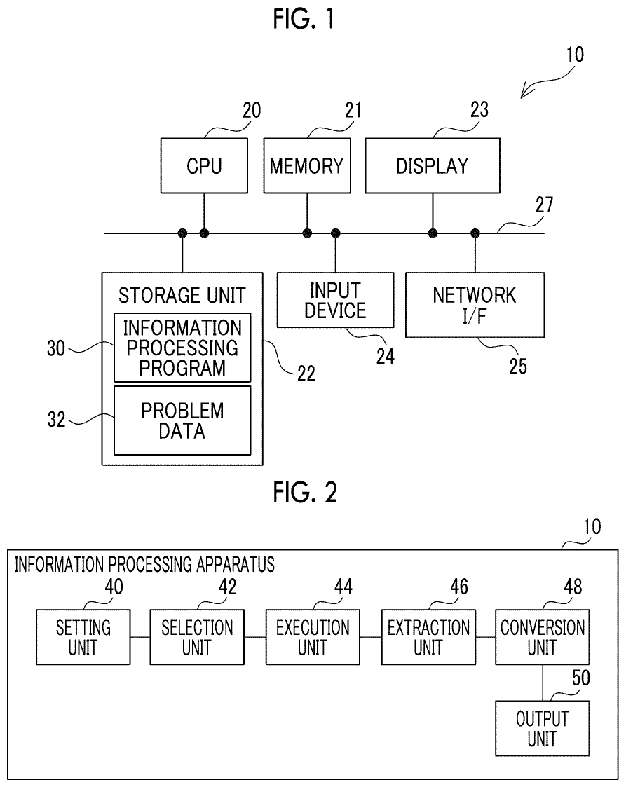

First, a hardware configuration of an information processing apparatus 10 according to the present embodiment will be described with reference to FIG. 1. Examples of the information processing apparatus 10 include a computer such as a personal computer or a server computer. As illustrated in FIG. 1, the information processing apparatus 10 includes a central processing unit (CPU) 20, a memory 21 as a transitory storage region, and a non-volatile storage unit 22. The information processing apparatus 10 also includes a display 23 such as a liquid crystal display, an input device 24 such as a keyboard and a mouse, and a network interface (I/F) 25 connected to a network. The CPU 20, the memory 21, the storage unit 22, the display 23, the input device 24, and the network I/F 25 are connected to a bus 27. The CPU 20 is an example of a processor according to the disclosed technology.

The storage unit 22 is implemented by a hard disk drive (HDD), a solid state drive (SSD), a flash memory, or the like. The storage unit 22 as a storage medium stores an information processing program 30. The CPU 20 reads out and loads the information processing program 30 into the memory 21 from the storage unit 22 and executes the loaded information processing program 30.

The storage unit 22 stores problem data 32 in which an optimization problem as a solution target for the information processing apparatus 10 is in a data form processable by the information processing apparatus 10. The problem data 32 includes a solution target element set that is an element set constituting the optimization problem as the solution target and that is composed of a plurality of elements. The problem data 32 also includes a constraint condition.

For example, the elements constituting the solution target element set means an operator, an operation date and time, and a product type of a product as an operation target, in a case where the optimization problem is a job-shop scheduling problem. A specific example of the solution target element set will be described in the examples described later.

The information processing apparatus 10 according to the present embodiment has a function of presenting a cause of inability to obtain a feasible solution to a user in a case where the feasible solution cannot be obtained in the optimization problem of the solution target. Hereinafter, a case where the optimization problem indicated by the problem data 32 is an optimization problem for which a feasible solution cannot be obtained will be illustratively described.

Next, a functional configuration of the information processing apparatus 10 according to the present embodiment will be described with reference to FIG. 2. As illustrated in FIG. 2, the information processing apparatus 10 includes a setting unit 40, a selection unit 42, an execution unit 44, an extraction unit 46, a conversion unit 48, and an output unit 50. The CPU 20 functions as the setting unit 40, the selection unit 42, the execution unit 44, the extraction unit 46, the conversion unit 48, and the output unit 50 by executing the information processing program 30.

The setting unit 40 first sets the solution target element set included in the problem data 32 as the tentative element set. The setting unit 40 adds 1 to a variable C for counting the number of times the execution unit 44, described later, determines that a tentative mathematical model is feasible. In a case where the execution unit 44, described later, determines that the tentative mathematical model, described later, is infeasible, the setting unit 40 sets an element set excluding an excluded element set, described later, from the tentative element set used in formulating the tentative mathematical model, as the tentative element set. That is, the tentative element set is either the solution target element or a partial element set of the solution target element set.

The selection unit 42 selects the excluded element set that is a subset of the tentative element set, from the tentative element set. In the present embodiment, the excluded element set is an element set of which exclusion of elements from the tentative element set makes the tentative mathematical model generated using the tentative clement set feasible. In a case where the selection unit 42 repeats executing processing of selecting the excluded element set from the tentative clement set, the selection unit 42 sets a set different from the excluded clement set selected so far as the excluded clement set. In the present embodiment, the selection unit 42 randomly selects the excluded element set from the tentative element set.

The execution unit 44 generates the tentative mathematical model that is a mathematical model in which the clement set excluding the excluded element set selected by the selection unit 42 from the tentative clement set and the constraint condition are formulated. During this generation, a condition related to the elements of the excluded element set is also excluded from the constraint condition. The execution unit 44 determines whether or not the generated tentative mathematical model is feasible. Specifically, for example, the execution unit 44 determines whether or not the tentative mathematical model is feasible by determining whether or not the feasible solution can be obtained from the tentative mathematical model using software called a solver for solving the optimization problem. This processing of solving the optimization problem uses a well-known algorithm such as a branch and bound method, a local search method, tabu search, simulated annealing, quantum annealing, a genetic algorithm, and swarm intelligence (for example, particle swarm optimization and ant colony optimization).

The setting unit 40 repeats executing processing of adding 1 to the variable C for counting the number of times the execution unit 44 determines that the tentative mathematical model is feasible until a predetermined condition (hereinafter, referred to as a “finish condition”) is satisfied. In a case where the execution unit 44 determines that the tentative mathematical model is infeasible, the setting unit 40 repeats executing processing of setting the element set excluding the excluded clement set from the tentative element set used in formulating the tentative mathematical model, as the tentative clement set until the finish condition is satisfied.

The selection unit 42 repeats executing the processing of selecting the excluded element set from the tentative clement set, until the finish condition is satisfied. The execution unit 44 generates the tentative mathematical model that is a mathematical model in which the element set excluding the excluded element set selected by the selection unit 42 from the tentative clement set and the constraint condition are formulated, and repeats executing processing of determining whether or not the generated tentative mathematical model is feasible until the finish condition is satisfied. As described above, in a case where the selection unit 42 repeats executing the processing of selecting the excluded element set from the tentative element set, the selection unit 42 sets a set different from the excluded clement set selected so far as the excluded element set. That is, the execution unit 44 executes the processing of determining whether or not the tentative mathematical model is feasible a plurality of times while changing the excluded element set.

Examples of the finish condition of the repeated processing include a condition that the number of consecutive times the tentative mathematical model is determined to be feasible is greater than or equal to a threshold value, and a condition that the number of times the repeated processing is executed exceeds an upper limit value.

In a case where the execution unit 44 determines that the tentative mathematical model is infeasible, the extraction unit 46 extracts a list of constraint conditions conflicting with each other (hereinafter, referred to as “conflicting constraints”) from the tentative mathematical model. In the present embodiment, in a case where the execution unit 44 at least once determines that the tentative mathematical model is feasible, and at least once determines that the tentative mathematical model is infeasible, the extraction unit 46 extracts the list of the conflicting constraints from the tentative mathematical model determined to be infeasible. For example, a function of the solver is used for extracting the list of the conflicting constraints.

The conversion unit 48 converts each conflicting constraint of the list extracted by the extraction unit 46 into a name of the constraint condition. Specifically, for example, the conversion unit 48 converts each conflicting constraint into the name of the constraint condition using a look-up table in which the constraint condition included in the problem data 32 and the name of the constraint condition are associated with each other.

The output unit 50 outputs the name of the constraint condition obtained by conversion performed by the conversion unit 48 to the display 23. Accordingly, the output unit 50 performs a control of displaying the name of the constraint condition on the display 23. The output unit 50 further outputs the excluded element set and the feasible solution in a case where the execution unit 44 determines that the tentative mathematical model is feasible, to the display 23 in a form set in accordance with the optimization problem. Accordingly, the output unit 50 performs a control of displaying the excluded element set and the feasible solution on the display 23 in the form set in accordance with the optimization problem. In this case, for example, the display form is set in advance in accordance with a type of the optimization problem.

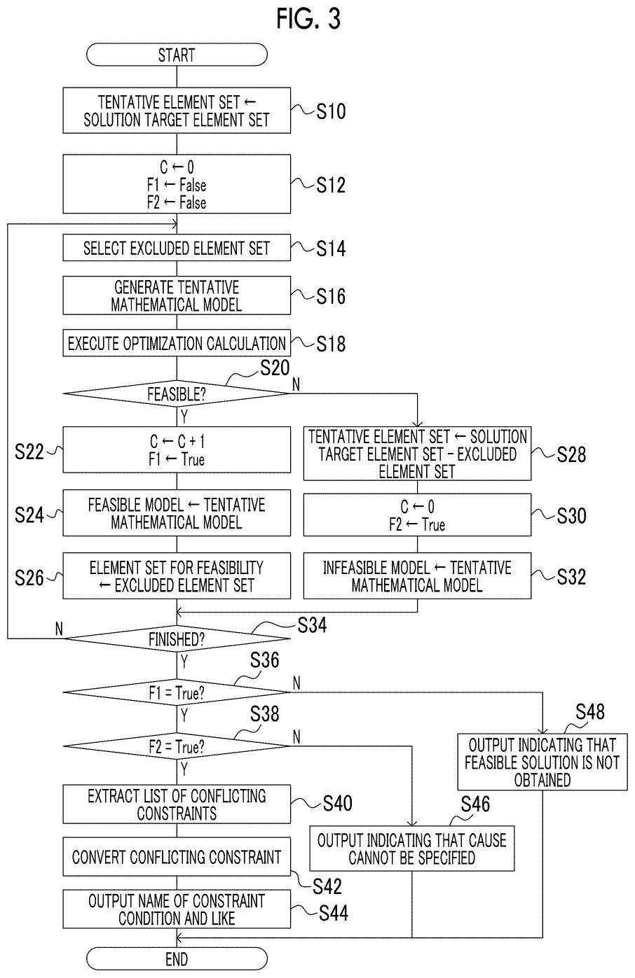

Next, an action of the information processing apparatus 10 according to the present embodiment will be described with reference to FIG. 3. The CPU 20 executes cause presentation processing illustrated in FIG. 3 by executing the information processing program 30. For example, the cause presentation processing illustrated in FIG. 3 is executed in a case where an execution start instruction is input by the user.

In step S10 in FIG. 3, the setting unit 40 sets the solution target element set included in the problem data 32 as the tentative element set. In step S12, the setting unit 40 sets the variable C for counting the number of times the execution unit 44 determines that the tentative mathematical model is feasible, to zero. The setting unit 40 sets a variable F1 indicating whether or not the execution unit 44 at least once determines that the tentative mathematical model is feasible, to False. The setting unit 40 sets a variable F2 indicating whether or not the execution unit 44 at least once determines that the tentative mathematical model is infeasible, to False.

In step S14, the selection unit 42, as described above, selects the excluded element set that is a subset of the tentative element set, from the tentative element set. In step S16, the execution unit 44, as described above, generates the tentative mathematical model that is a mathematical model in which the element set (hereinafter, referred to as a “difference element set”) excluding the excluded element set selected in step S14 from the tentative element set and the constraint condition are formulated. In step S18, the execution unit 44 executes optimization calculation on the tentative mathematical model generated in step S16, using software called a solver for solving the optimization problem.

In step S20, the execution unit 44 determines whether or not the tentative mathematical model is feasible by determining whether or not the feasible solution is obtained from the tentative mathematical model as a result of executing the optimization calculation in step S18. In a case where this determination results in a positive determination, the processing transitions to step S22.

In step S22, the setting unit 40 adds 1 to the variable C. The setting unit 40 sets the variable F1 to True. In step S24, the setting unit 40 stores the tentative mathematical model as a feasible model separately from the tentative mathematical model. In step S26, the setting unit 40 stores the excluded element set as an element set for making the tentative mathematical model feasible, separately from the excluded element set. In a case where the processing in step S26 is finished, the processing transitions to step S34.

In a case where the determination in step S20 results in a negative determination, the processing transitions to step S28. In step S28, the setting unit 40 sets the element set excluding the excluded element set from the tentative element set used in formulating the tentative mathematical model, as the tentative element set. In step S30, the setting unit 40 sets the variable C to zero. The setting unit 40 sets the variable F2 to True. In step S32, the setting unit 40 stores the tentative mathematical model as an infeasible model separately from the tentative mathematical model. In a case where the processing in step S32 is finished, the processing transitions to step S34.

In step S34, the execution unit 44 determines whether or not the finish condition of the repeated processing from step S14 to step S32 is satisfied. Specifically, the execution unit 44 determines whether or not the number of consecutive times the tentative mathematical model is determined to be feasible is greater than or equal to the threshold value by determining whether or not a value stored in the variable C is greater than or equal to the threshold value. The execution unit 44 determines whether or not the number of times the repeated processing is executed exceeds the upper limit value. In a case where the determination in step S34 results in a negative determination, the processing returns to step S14. In a case where the determination in step S34 results in a positive determination, the processing transitions to step S36.

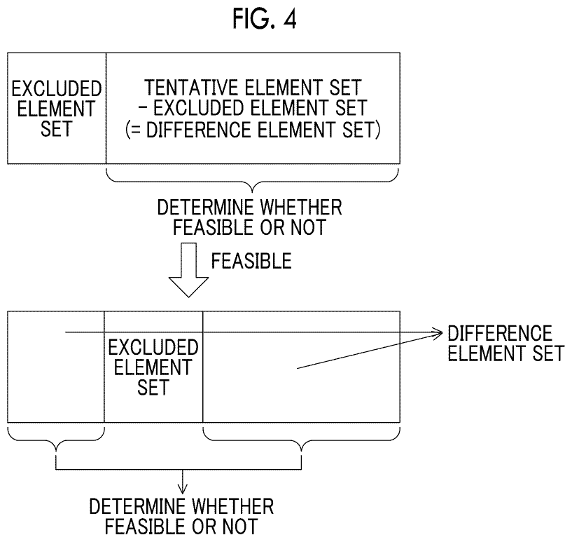

As illustrated in FIG. 4, in a case where the tentative mathematical model generated based on the difference element set is determined to be feasible, the tentative element set is not updated. In this case, in step S14 executed subsequently, a different excluded element set is selected from the tentative element set, and whether or not the tentative mathematical model generated based on a new difference element set excluding the excluded element set from the tentative element set is feasible is determined.

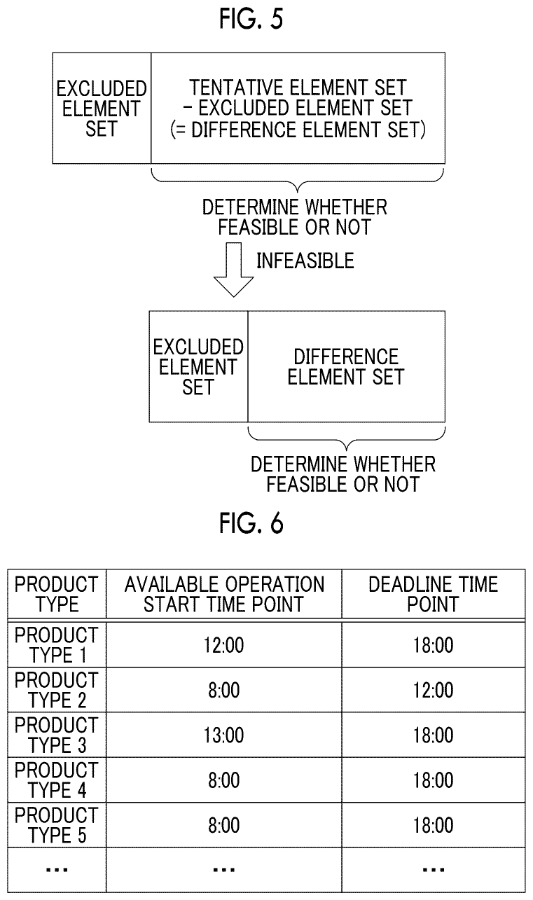

As illustrated in FIG. 5, in a case where the tentative mathematical model generated based on the difference element set is determined to be infeasible, the tentative element set is updated by setting the difference element set as the tentative element set in step S28. In this case, in step S14 executed subsequently, the excluded element set is selected from the new tentative element set, and whether or not the tentative mathematical model generated based on the new difference element set excluding the excluded element set from the new tentative element set is feasible is determined.

In step S36, the extraction unit 46 determines whether or not the execution unit 44 at least once determines that the tentative mathematical model is feasible, by determining whether or not the variable F1 is True. In a case where this determination results in a positive determination, the processing transitions to step S38. In step S38, the extraction unit 46 determines whether or not the execution unit 44 at least once determines that the tentative mathematical model is infeasible, by determining whether or not the variable F2 is True. In a case where this determination results in a positive determination, the processing transitions to step S40.

In step S40, the extraction unit 46, as described above, extracts the list of the conflicting constraints from the tentative mathematical model determined to be infeasible. The tentative mathematical model determined to be infeasible is the infeasible model stored in step S32. In step S42, the conversion unit 48, as described above, converts each conflicting constraint of the list extracted in step S40 into the name of the constraint condition.

In step S44, the output unit 50, as described above, outputs the name of the constraint condition obtained by conversion in step S42 to the display 23. The output unit 50, as described above, further outputs the excluded element set and the feasible solution in a case where the execution unit 44 determines that the tentative mathematical model is feasible, to the display 23 in the form set in accordance with the optimization problem. The excluded element set in a case where the tentative mathematical model is determined to be feasible is the element set for making the tentative mathematical model stored in step S26 feasible. The feasible solution in a case where the tentative mathematical model is determined to be feasible is the feasible solution obtained from the feasible model stored in step S24. In a case where the processing in step S44 is finished, the cause presentation processing is finished.

Meanwhile, in a case where the determination in step S38 results in a negative determination, the processing transitions to step S46. In step S46, the output unit 50 outputs a message indicating that a determination indicating infeasibility is not made even once and that the cause of the inability to obtain the feasible solution of the optimization problem cannot be specified, to the display 23. In a case where the processing in step S46 is finished, the cause presentation processing is finished. In a case where the determination in step S36 results in a negative determination, the processing transitions to step S48. In step S48, the output unit 50 outputs a message indicating that the feasible solution is not obtained even once, to the display 23. In a case where the processing in step S48 is finished, the cause presentation processing is finished.

Next, three examples including first to third examples will be described.

### First Example

In the first example, an example of applying the disclosed technology to the job-shop scheduling problem will be described. Specifically, in the first example, the solution target is an optimization problem for planning to complete an operation related to production of a product type of a product to be produced within a period as quickly as possible by efficiently assigning the operation to a plurality of operators.

The problem data 32 according to the first example includes the product type data illustrated in FIG. 6. As illustrated in FIG. 6, for each product type of a production target, an available operation start time point for the product type and a deadline time point for the product type are associated with each other in the product type data.

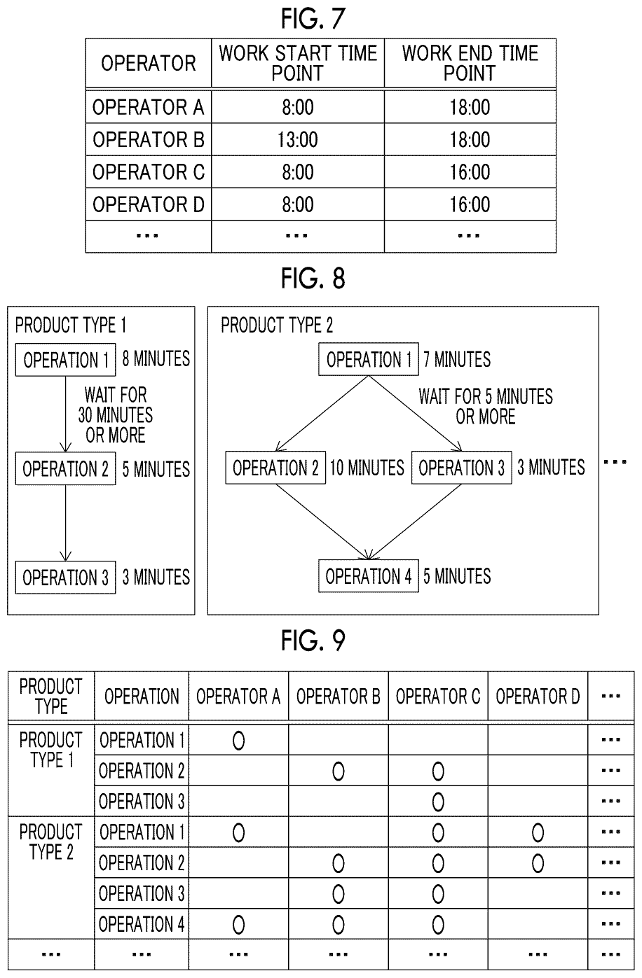

The problem data 32 according to the first example also includes the operator data illustrated in FIG. 7. As illustrated in FIG. 7, for each operator, a work start time point and a work end time point of the operator are associated with each other in the operator data.

The problem data 32 according to the first example also includes the operation order data illustrated in FIG. 8. As illustrated in FIG. 8, the operation order data includes, for each product type, an operation required for producing the product type, an operation order constraint, a required time for the operation, and a waiting time required after the operation. In the example in FIG. 8, an arrow indicates the operation order constraint, a time near the arrow indicates the waiting time after the operation is finished, and a time on a right side of the operation indicates the required time for the operation. In the example in FIG. 8, an arrow without the waiting time indicates that the waiting time is zero. The example in FIG. 8 indicates that, for Product Type 1, Operation 2 is performed after waiting for at least 30 minutes after Operation 1 is finished, and Operation 3 is performed after Operation 2. The example in FIG. 8 indicates that, for Product Type 1, the required time for Operation 1 is 8 minutes, the required time for Operation 2 is 5 minutes, and the required time for Operation 3 is 3 minutes.

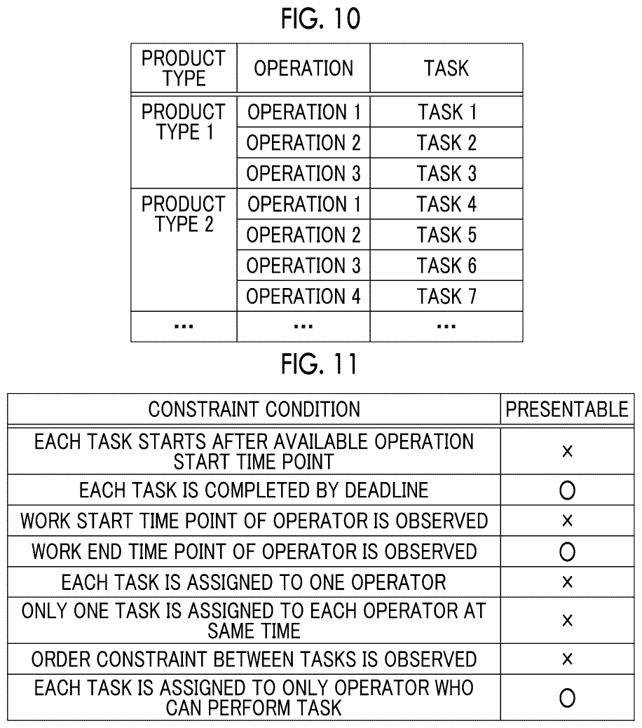

The problem data 32 according to the first example also includes the data related to skill of the operator illustrated in FIG. 9. As illustrated in FIG. 9, the data related to the skill of the operator includes, for each combination of the product type and the operation, information indicating whether or not each operator can perform the operation on the product type. In the example in FIG. 9, a field with a circle mark indicates that the operator can perform the operation on the product type, and a blank field indicates that the operator cannot perform the operation on the product type. The example in FIG. 9 indicates that Operator A can perform Operation 1 and cannot perform Operations 2 and 3 for Product Type 1, and can perform Operations 1 and 4 and cannot perform Operations 2 and 3 for Product Type 2.

As illustrated in FIG. 10, in the first example, the combination of the product type and the operation is treated as a task. The example in FIG. 10 indicates that a combination of Product Type 1 and Operation 1 is Task 1.

In the first example, the above data will be represented using the following symbols.
i∈T={Task 1, Task 2, . . . }: Set of tasks
pᵢi: Required time for task i
sᵢ^{startble}: Available operation start time point of task i
eᵢ^{deadline}: Deadline time point of task i
w∈W={Operator A, Operator B, . . . }: Set of operators
s_{w}^{shift}: Work start time point of operator w
e_{w}^{shift}: Work end time point of operator w
(i, j)∈T^{precedence}: Pair of tasks subjected to order constraint
p_{i,j}^{span}(∀i, j∈T^{precedence}): Minimum waiting time between task i and task j
q_{i,w}: Whether or not operator w is able to perform task i (0: unable, 1: able)

The problem data 32 according to the first example also includes a decision variable, a constraint condition, and an objective function for formulating a mixed integer linear programming problem. The decision variable is defined as sᵢ and a_{i,w} illustrated below.
sᵢ(i∈T): Start time point of task i
a_{i,w}(i∈T, w∈W): Whether or not to assign task i to operator w (0: do not assign, 1: assign)

The constraint condition is indicated by Expressions (1) to (8). Expression (1) indicates a condition that each task starts after the available operation start time point. Expression (2) indicates a condition that each task is completed by a deadline. Expression (3) indicates a condition that the work start time point of the operator is observed. Expression (4) indicates a condition that the work end time point of the operator is observed. Expression (5) indicates a condition that each task is assigned to one operator. Expression (6) indicates a condition that only one task is assigned to each operator at the same time. Expression (7) indicates a condition that the order constraint between tasks is observed. Expression (8) indicates a condition that each task is assigned to only an operator who can perform the task.

$${s}_{i}^{startble} \leq {s}_{i} , ∀ i ∈ T \qquad ( 1 )$$

$${s}_{i} + {p}_{i} \leq {e}_{i}^{deadline} , ∀ i ∈ T \qquad ( 2 )$$

$${s}_{w}^{shift} \cdot {a}_{i , w} \leq {s}_{i} , ∀ i ∈ T , w ∈ W \qquad ( 3 )$$

$${s}_{i} + {a}_{i , w} \cdot {p}_{i} \leq {e}_{w}^{shift} , ∀ i ∈ T , w ∈ W \qquad ( 4 )$$

$${\sum }_{w} {a}_{i , w} = 1 , ∀ i ∈ T \qquad ( 5 )$$

$$\begin{matrix}{e}_{i} \leq {s}_{j} + M ( 3 - {a}_{i , w} - {a}_{j , w} - {o}_{i , j , w} ) \\ {e}_{j} \leq {s}_{i} + M ( 2 - {a}_{i , w} - {a}_{j , w} + {o}_{i , j , w} )\end{matrix} \} \qquad ( 6 )$$

$$M is a sufficiently large integer \\ o is a 0 - 1 variable required for formulation$$

$${s}_{i} + {p}_{i} + {p}_{i , j}^{span} \leq {s}_{j} , ∀ ( i , j ) ∈ {T}^{precedence} \qquad ( 7 )$$

$${a}_{i , w} = 0 , ∀ ( i , j ) ∈ \{ i , w \vert i ∈ T , w ∈ W , {q}_{i , w} = 0 \} \qquad ( 8 )$$

The objective function is set to complete the last completed task as quickly as possible and is indicated by Expressions (9) and (10).

$$min \{ C \} \qquad ( 9 )$$

$${s}_{i} + {p}_{i} \leq C , ∀ i ∈ T \qquad ( 10 )$$

In the first example, in selecting the excluded element set from the tentative element set, the selection unit 42 selects a task as an excluded element. A reason for this is that, in a case where the tentative mathematical model is determined to be infeasible, reducing the number of operators results in a low probability of obtaining the feasible solution, and gradually reducing the number of tasks can obtain the feasible solution when the number of tasks reaches a certain number.

That is, in the first example, in a case where the tentative mathematical model is determined to be feasible, the tentative mathematical model is generated again after changing the task to be selected as the excluded element set, and whether or not the tentative mathematical model is feasible is determined. In the first example, in a case where the tentative mathematical model is determined to be infeasible, the tentative mathematical model is generated again after reducing the number of tasks, and whether or not the tentative mathematical model is feasible is determined.

As illustrated in FIG. 11, in the first example, whether or not each constraint condition is presentable to the user is set. The constraint condition with a circle mark in the presentable column illustrated in FIG. 11 is a presentation target for the user. In the example in FIG. 11, the constraint condition indicated by Expression (2), the constraint condition indicated by Expression (4), and the constraint condition indicated by Expression (8) are the presentation target for the user. A reason why these constraint conditions are the presentation target for the user is that these constraint conditions are considered to provide a method for alleviation as a countermeasure method for a case where the feasible solution cannot be obtained. For example, for the constraint condition indicated by Expression (2), a method of extending the deadline of the product type is considered as the countermeasure method for a case where the feasible solution cannot be obtained. For example, for the constraint condition indicated by Expression (4), a method of asking the operator to work overtime is considered as the countermeasure method for a case where the feasible solution cannot be obtained. For example, for the constraint condition indicated by Expression (8), a method such as recruiting and training of the operator who can perform the target task is considered as the countermeasure method for a case where the feasible solution cannot be obtained.

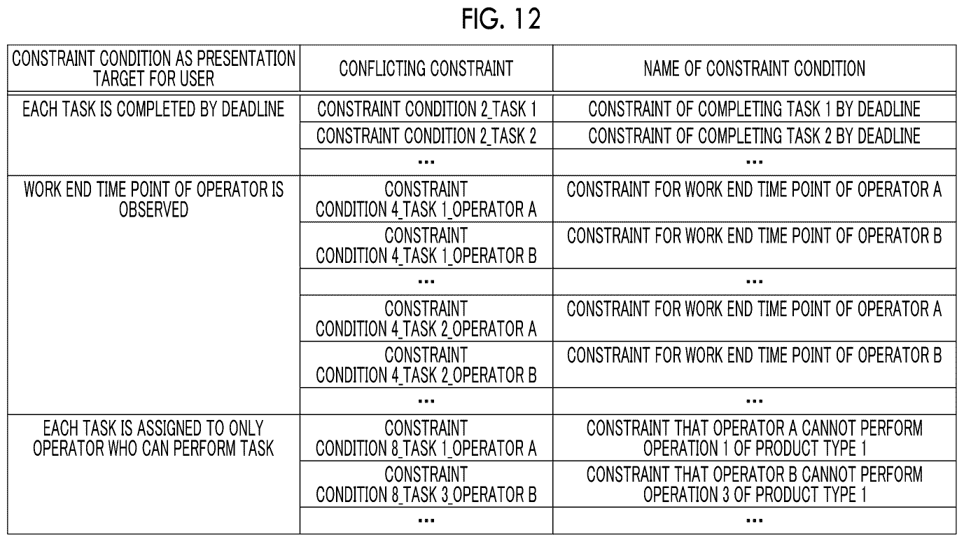

In a case where the list of the conflicting constraints extracted by the extraction unit 46 includes the constraint condition as the presentation target for the user, the conversion unit 48 converts the conflicting constraint into the name of the constraint condition. In the first example, the conversion unit 48 converts the conflicting constraint into the name of the constraint condition using the look-up table illustrated in FIG. 12.

As illustrated in FIG. 12, in the look-up table, each conflicting constraint is associated with the name of the constraint condition understandable by the user. For example, in a case where the condition that Task I is completed by the deadline in the constraint condition of Expression (2) is not satisfied and changes to a conflicting constraint, the conflicting constraint is converted into the name of the constraint condition “constraint of completing Task 1 by deadline”.

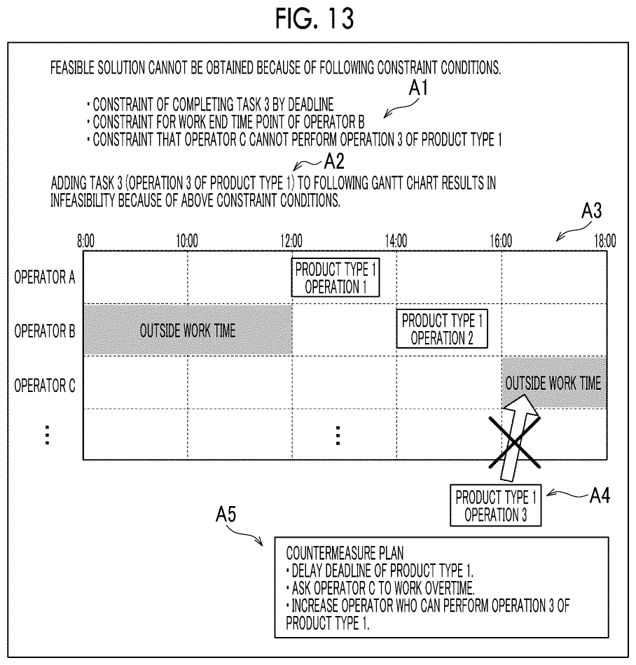

FIG. 13 illustrates an example of a presentation screen for the user output by the output unit 50 to be displayed on the display 23. As illustrated in FIG. 13, a name A1 of the constraint condition obtained by conversion performed by the conversion unit 48 is displayed on the presentation screen for the user. On the presentation screen for the user, an excluded element set A2 in a case where the execution unit 44 determines that the tentative mathematical model is feasible, that is, the element set for making the tentative mathematical model feasible, is displayed in a character string form. On the presentation screen for the user, a feasible solution A3 in a case where the tentative mathematical model is determined to be feasible, that is, the feasible solution obtained from the feasible model, is displayed in a Gantt chart form set in accordance with the optimization problem. On the presentation screen for the user, an excluded element set A4 in a case where the execution unit 44 determines that the tentative mathematical model is feasible is displayed in a form that visualizes infeasibility in a case where the excluded element set A4 is added to the Gantt chart. On the presentation screen for the user, a countermeasure plan A5 for obtaining the feasible solution is also displayed. This countermeasure plan is displayed based on a condition for satisfying the conflicting constraint.

### Second Example

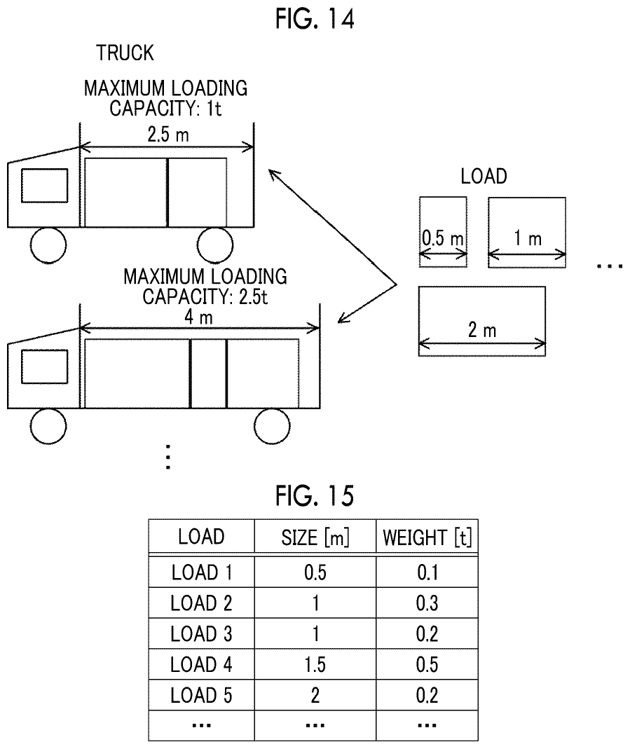

In the second example, an example of applying the disclosed technology to a bin packing problem will be described. Specifically, as illustrated in FIG. 14, in the second example, the solution target is an optimization problem for distributing a plurality of loads that are different in at least one of size or weight to a plurality of trucks that are different in at least one of size or maximum loading capacity. In the second example, all loads have to be loaded on the truck, and an operating cost (for example, a gasoline cost) of the truck is as low as possible. In the second example, a width of each load and a width of each truck match, and neither the loads can be stacked in a height direction nor the loads can be rotated.

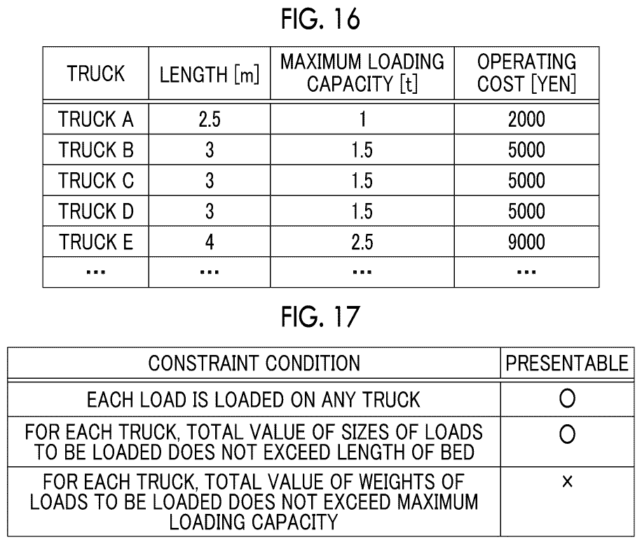

The problem data 32 according to the second example includes the load data illustrated in FIG. 15. As illustrated in FIG. 15, the load data includes the size and the weight of each load. The problem data 32 according to the second example also includes the truck data illustrated in FIG. 16. As illustrated in FIG. 16, the truck data includes a length of a bed, the maximum loading capacity, and the operating cost of each truck.

In the second example, the above data will be represented using the following symbols.
i∈B={Load 1, Load 2, . . . }: Set of loads
lᵢ: Size of load i
wᵢ: Weight of load i
j∈T={Truck A, Truck B, . . . }: Set of trucks
Lⱼ: Length of bed of truck j
Wⱼ: Maximum loading capacity of truck j
Cⱼ: Operating cost of truck j

The problem data 32 according to the second example also includes a decision variable, a constraint condition, and an objective function, as in the first example. The decision variable is defined as x_{i,j} and yⱼ illustrated below.
x_{i,j}(i∈B, j∈T): Whether or not to load load i on truck j (0: do not load, 1: load)
yᵢ(j∈T): Whether or not to operate truck j (0: do not operate, 1: operate)

The constraint condition is indicated by Expressions (11) to (13). Expression (11) indicates a condition that each load is loaded on any truck. Expression (12) indicates a condition that a total value of the sizes of the loads to be loaded does not exceed the length of the bed for each truck. Expression (13) indicates a condition that a total value of the weights of the loads to be loaded does not exceed the maximum loading capacity for each truck.

$${\sum }_{j ∈ T} {x}_{i , j} = 1 , ∀ i ∈ B \qquad ( 11 )$$

$${\sum }_{j ∈ T} {l}_{i} {x}_{i , j} \leq {L}_{j} {y}_{j} , ∀ i ∈ T \qquad ( 12 )$$

$${\sum }_{j ∈ T} {w}_{i} {x}_{i , j} \leq {W}_{j} {y}_{j} , ∀ i ∈ T \qquad ( 13 )$$

The objective function is set to minimize the operating cost of the truck and is indicated by Expression (14).

$$min {\sum }_{j} {C}_{j} {y}_{j} \qquad ( 14 )$$

In the second example, in selecting the excluded element set from the tentative element set, the selection unit 42 selects a load as an excluded element. A reason for this is that, in a case where the tentative mathematical model is determined to be infeasible, reducing the number of trucks results in a low probability of obtaining the feasible solution, and gradually reducing the number of loads can obtain the feasible solution when the number of loads reaches a certain number.

That is, in the second example, in a case where the tentative mathematical model is determined to be feasible, the tentative mathematical model is generated again after changing the load to be selected as the excluded clement set, and whether or not the tentative mathematical model is feasible is determined. In the second example, in a case where the tentative mathematical model is determined to be infeasible, the tentative mathematical model is generated again after reducing the number of loads, and whether or not the tentative mathematical model is feasible is determined.

As illustrated in FIG. 17, in the second example, whether or not each constraint condition is presentable to the user is set. The constraint condition with a circle mark in the presentable column illustrated in FIG. 17 is a presentation target for the user. In the example in FIG. 17, the constraint condition indicated by Expression (11) and the constraint condition indicated by Expression (12) are the presentation target for the user. A reason why these constraint conditions are the presentation target for the user is that these constraint conditions are considered to provide a method for alleviation as a countermeasure method for a case where the feasible solution cannot be obtained. For example, for the constraint condition indicated by Expression (11), a method of selecting a load not to be loaded on the truck is considered as the countermeasure method for a case where the feasible solution cannot be obtained. For example, for the constraint condition indicated by Expression (12), a method of loading a load on the bed of the truck in a state where the load slightly protrudes from the bed of the truck is considered as the countermeasure method for a case where the feasible solution cannot be obtained.

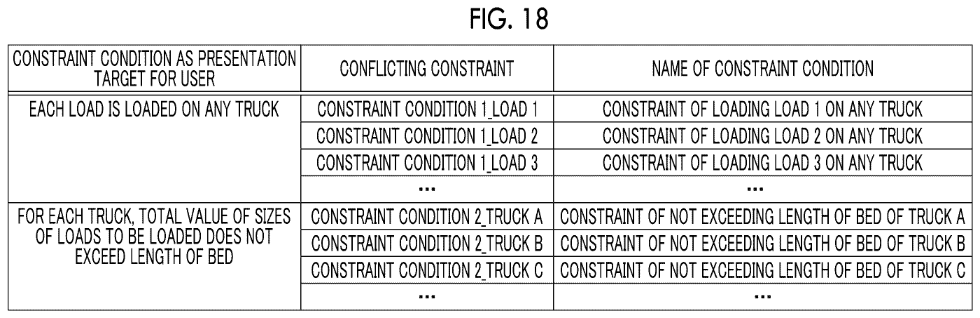

In a case where the list of the conflicting constraints extracted by the extraction unit 46 includes the constraint condition as the presentation target for the user, the conversion unit 48 converts the conflicting constraint into the name of the constraint condition. In the second example, the conversion unit 48 converts the conflicting constraint into the name of the constraint condition using the look-up table illustrated in FIG. 18.

As illustrated in FIG. 18, in the look-up table, each conflicting constraint is associated with the name of the constraint condition understandable by the user. For example, in a case where the condition that Load 1 is loaded on any truck in the constraint condition of Expression (11) is not satisfied and changes to a conflicting constraint, the conflicting constraint is converted into the name of the constraint condition “constraint of loading Load 1 on any truck”.

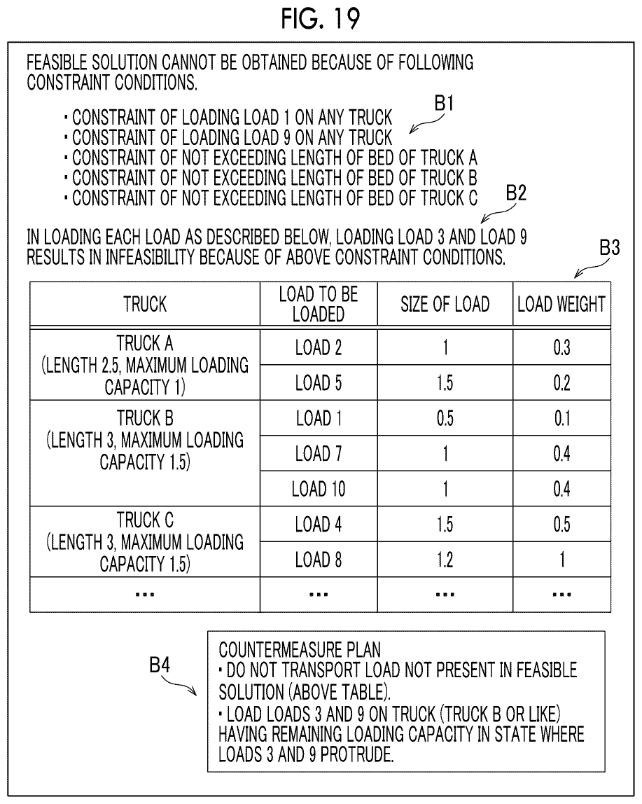

FIG. 19 illustrates an example of a presentation screen for the user output by the output unit 50 to be displayed on the display 23. As illustrated in FIG. 19, a name B1 of the constraint condition obtained by conversion performed by the conversion unit 48 is displayed on the presentation screen for the user. On the presentation screen for the user, an excluded element set B2 in a case where the execution unit 44 determines that the tentative mathematical model is feasible, that is, the element set for making the tentative mathematical model feasible, is displayed in a character string form. On the presentation screen for the user, a feasible solution B3 in a case where the tentative mathematical model is determined to be feasible, that is, the feasible solution obtained from the feasible model, is displayed in a table form set in accordance with the optimization problem. On the presentation screen for the user, a countermeasure plan B4 for obtaining the feasible solution is also displayed. This countermeasure plan is displayed based on a condition for satisfying the conflicting constraint.

### Third Example

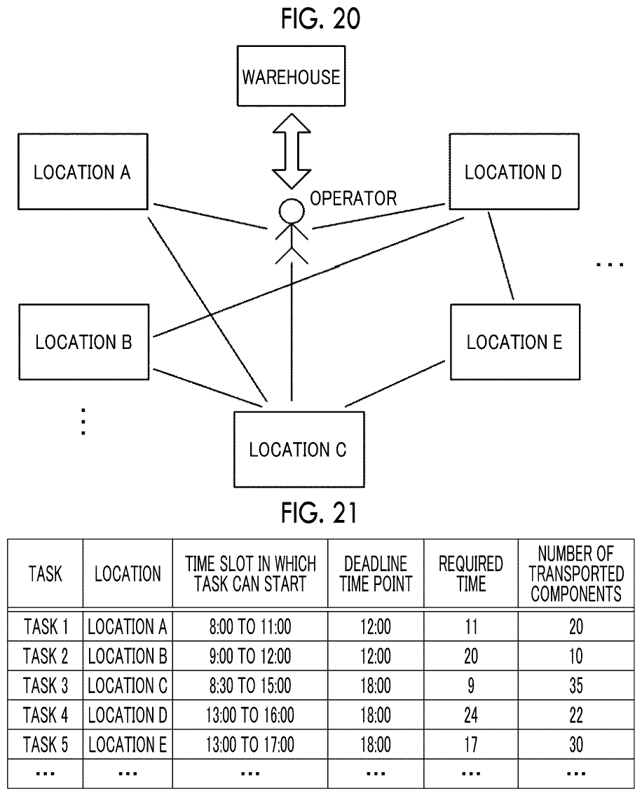

In the third example, an example of applying the disclosed technology to a transportation problem will be described. Specifically, as illustrated in FIG. 20, in the third example, the solution target is an optimization problem in which an operator who departs from one warehouse performs an operation at each location and returns to the warehouse through locations of a plurality of transportation destinations. In the third example, the operator replenishes necessary components from the warehouse at each location, performs an operation for a predetermined time at each location, and moves to another location.

The problem data 32 according to the third example includes the transportation task data illustrated in FIG. 21. A transportation task means a task in which the operator transports a component taken from the warehouse to a location of a transportation destination and performs the operation using the component. As illustrated in FIG. 21, the transportation task data includes, for each transportation task, the location of the transportation destination, a time slot in which the task can start, a deadline time point of the task, a required time for the task, and the number of components required to be transported by the operator (hereinafter, referred to as “the number of transported components”).

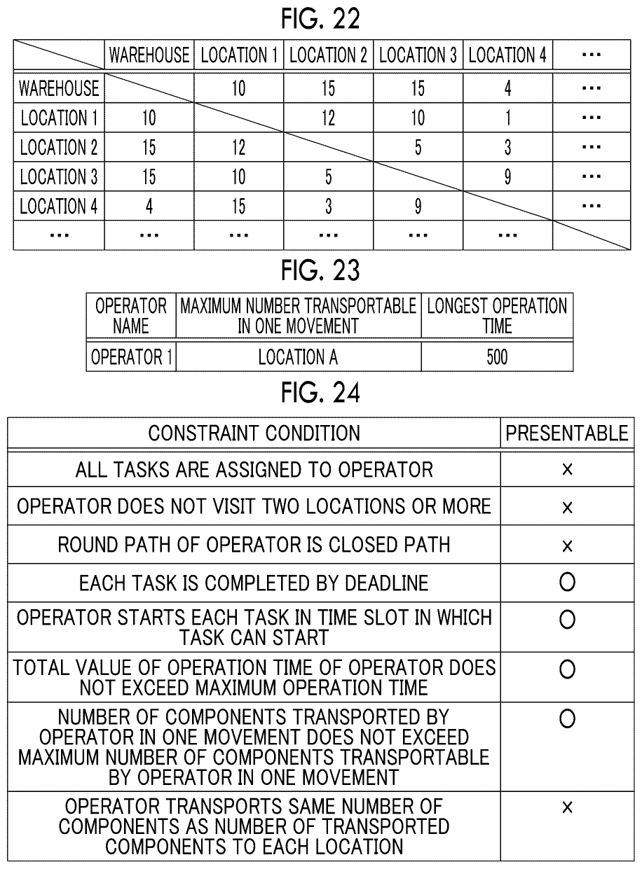

The problem data 32 according to the third example also includes the moving time data illustrated in FIG. 22. As illustrated in FIG. 22, the moving time data includes a moving time of the operator between two locations including the warehouse and the location of each transportation destination.

The problem data 32 according to the third example also includes the operator information illustrated in FIG. 23. As illustrated in FIG. 23, the operator information includes the maximum number of components transportable by the operator in one movement and a daily longest operation time of the operator.

The problem data 32 according to the third example also includes a decision variable, a constraint condition, and an objective function, as in the first and second examples. The decision variable includes the following two variables.
(1) A 0-1 variable that is set to 1 in a case where the operator performs the task in an r-th round.
(2) A 0-1 variable that is set to 1 in a case where the operator performs a task i and a task j in this order in the r-th round.

The constraint condition includes the following eight conditions.
(1) All tasks are assigned to the operator.
(2) The operator does not visit two or more locations at the same time.
(3) A round path of the operator is a closed path.
(4) Each task is completed by the deadline.
(5) The operator starts each task in the time slot in which the task can start.
(6) A total value of an operation time of the operator does not exceed a maximum operation time.
(7) The number of components transported by the operator in one movement does not exceed the maximum number of components transportable by the operator in one movement.
(8) The operator transports the same number of components as the number of transported components to each location.

The objective function is set to complete all tasks as quickly as possible.

In the third example, in selecting the excluded element set from the tentative element set, the selection unit 42 selects a task as an excluded element. A reason for this is that, in a case where the tentative mathematical model is determined to be infeasible, reducing the number of tasks can obtain the feasible solution when the number of tasks reaches a certain number.

That is, in the third example, in a case where the tentative mathematical model is determined to be feasible, the tentative mathematical model is generated again after changing the task to be selected as the excluded element set, and whether or not the tentative mathematical model is feasible is determined. In the third example, in a case where the tentative mathematical model is determined to be infeasible, the tentative mathematical model is generated again after reducing the number of tasks, and whether or not the tentative mathematical model is feasible is determined.

As illustrated in FIG. 24, in the third example, whether or not each constraint condition is presentable to the user is set. The constraint condition with a circle mark in the presentable column illustrated in FIG. 24 is a presentation target for the user. In the example in FIG. 24, the constraint conditions of (4) to (7) are the presentation target for the user. A reason why these constraint conditions are the presentation target for the user is that these constraint conditions are considered to provide a method for alleviation as a countermeasure method for a case where the feasible solution cannot be obtained. For example, for the constraint condition of (4), a method of requesting extension of the deadline time point is considered as the countermeasure method for a case where the feasible solution cannot be obtained. For example, for the constraint condition of (5), a method of adjusting an operating time slot of equipment corresponding to the task and a transportation date of the component is considered as the countermeasure method for a case where the feasible solution cannot be obtained. For example, for the constraint condition of (6), a method of asking the operator to work overtime is considered as the countermeasure method for a case where the feasible solution cannot be obtained. For example, for the constraint condition of (7), a method of increasing the number of components transportable by the operator in one movement is considered as the countermeasure method for a case where the feasible solution cannot be obtained.

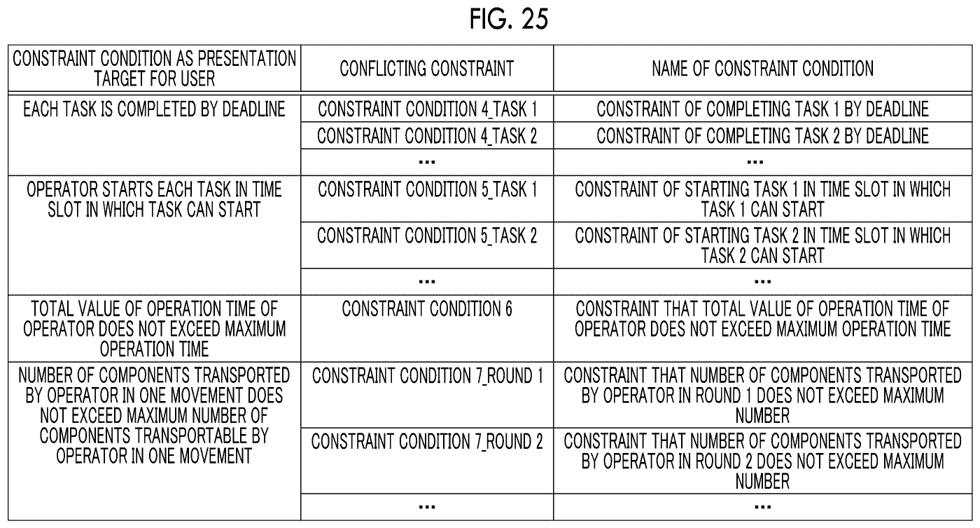

In a case where the list of the conflicting constraints extracted by the extraction unit 46 includes the constraint condition as the presentation target for the user, the conversion unit 48 converts the conflicting constraint into the name of the constraint condition. In the third example, the conversion unit 48 converts the conflicting constraint into the name of the constraint condition using the look-up table illustrated in FIG. 25.

As illustrated in FIG. 25, in the look-up table, each conflicting constraint is associated with the name of the constraint condition understandable by the user. For example, in a case where the condition that Task 1 is completed by the deadline in the constraint condition of (4) is not satisfied and changes to a conflicting constraint, the conflicting constraint is converted into the name of the constraint condition “constraint of completing Task 1 by deadline”.

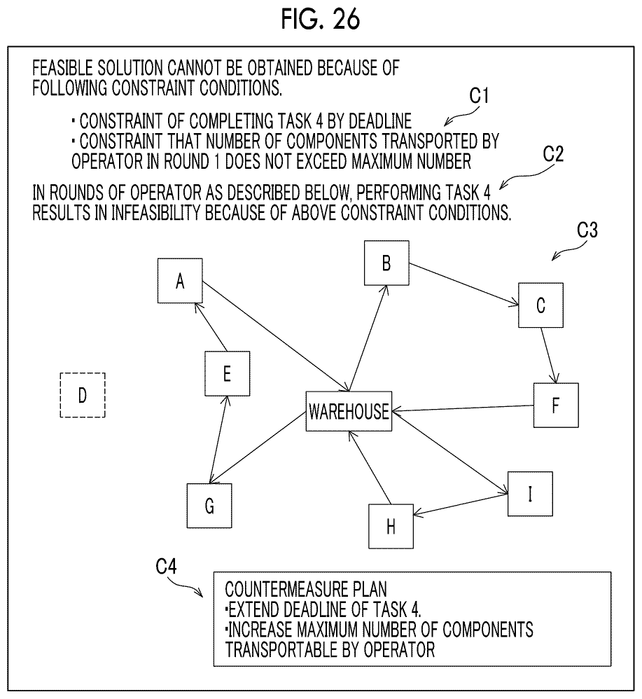

FIG. 26 illustrates an example of a presentation screen for the user output by the output unit 50 to be displayed on the display 23. As illustrated in FIG. 26, a name C1 of the constraint condition obtained by conversion performed by the conversion unit 48 is displayed on the presentation screen for the user. On the presentation screen for the user, an excluded element set C2 in a case where the execution unit 44 determines that the tentative mathematical model is feasible, that is, the element set for making the tentative mathematical model feasible, is displayed in a character string form. On the presentation screen for the user, a feasible solution C3 in a case where the tentative mathematical model is determined to be feasible, that is, the feasible solution obtained from the feasible model, is displayed in a directed graph form set in accordance with the optimization problem. On the presentation screen for the user, a countermeasure plan C4 for obtaining the feasible solution is also displayed. This countermeasure plan is displayed based on a condition for satisfying the conflicting constraint.

As described above, according to the present embodiment, the cause of the inability to obtain the feasible solution in the optimization problem can be presented to the user in a form understandable by the user.

In the embodiment, presenting various types of information to the user by outputting the information to the display 23 via the output unit 50 has been described. However, the present disclosure is not limited to this. For example, the present disclosure may include an aspect in which the output unit 50 presents various types of information to the user by outputting the information to an audio output device such as a speaker.

In the embodiment, for example, the following various processors can be used as a hardware structure of a processing unit that executes various types of processing, such as each functional unit of the information processing apparatus 10. The various processors include, in addition to a CPU that is a general-purpose processor functioning as various processing units by executing software (a program) as described above, a programmable logic device (PLD) such as a field programmable gate array (FPGA) that is a processor having a circuit configuration changeable after manufacture, a dedicated electric circuit such as an application specific integrated circuit (ASIC) that is a processor having a circuit configuration dedicatedly designed to execute specific processing, and the like.

One processing unit may be composed of one of the various processors or may be composed of a combination of two or more processors of the same type or different types (for example, a combination of a plurality of FPGAs or a combination of a CPU and an FPGA). A plurality of processing units may be composed of one processor.

Examples of the plurality of processing units composed of one processor include, first, a form of one processor composed of a combination of one or more CPUs and software, in which the processor functions as the plurality of processing units, as represented by a computer such as a client and a server. Second, examples include a form of using a processor that implements functions of an entire system including the plurality of processing units in one integrated circuit (IC) chip, as represented by a system on chip (SoC). Accordingly, various processing units are configured using one or more of the various processors as the hardware structure.

More specifically, an electric circuit (circuitry) in which circuit elements such as semiconductor elements are combined can be used as the hardware structure of the various processors.

In the embodiment, an aspect in which the information processing program 30 is stored (installed) in advance in the storage unit 22 has been described. However, the present disclosure is not limited to this. The information processing program 30 may be provided in a form of a recording on a recording medium such as a compact disc read only memory (CD-ROM), a digital versatile disc read only memory (DVD-ROM), and a universal serial bus (USB) memory. The information processing program 30 may also be provided in a form of a download from an external apparatus through a network.

The disclosure of JP2022-115039 filed on Jul. 19, 2022 is incorporated in the present specification by reference in its entirety. All documents, patent applications, and technical standards described in the present specification are incorporated in the present specification by reference to the same extent as in a case where individual documents, patent applications, and technical standards are specifically and individually indicated to be incorporated by reference.

What is claimed is:

1. An information processing apparatus comprising:
a processor,
wherein the processor is configured to:
select an excluded element set that is a subset of a tentative element set, from the tentative element set that is at least a part of a solution target element set which is an element set constituting an optimization problem as a solution target and which is composed of a plurality of elements;
determine whether or not a tentative mathematical model that is a mathematical model in which an element set excluding the excluded element set from the tentative element set and a constraint condition are formulated, is feasible;
in a case where the tentative mathematical model is determined to be infeasible, extract a list of constraint conditions conflicting with each other from the tentative mathematical model;
convert each constraint condition of the extracted list into a name of the constraint condition; and
output the name of the constraint condition obtained by conversion.

2. The information processing apparatus according to claim 1,
wherein the processor is configured to:
execute processing of determining whether or not the tentative mathematical model is feasible a plurality of times while changing the excluded element set; and
further output the excluded element set and a feasible solution in a case where the tentative mathematical model is determined to be feasible, in a form set in accordance with the optimization problem.

3. The information processing apparatus according to claim 2,
wherein the processor is configured to, in a case where the tentative mathematical model is determined to be feasible at least once, and the tentative mathematical model is determined to be infeasible at least once, extract a list of constraint conditions conflicting with each other from the tentative mathematical model determined to be infeasible.

4. The information processing apparatus according to claim 2,
wherein the processor is configured to repeat executing, until a predetermined condition is satisfied,
processing of selecting the excluded element set from the tentative element set,
processing of determining whether or not the tentative mathematical model is feasible,
processing of, in a case where the tentative mathematical model is determined to be feasible, adding 1 to the number of times the tentative mathematical model is determined to be feasible, and
processing of, in a case where the tentative mathematical model is determined to be infeasible, setting the element set excluding the excluded element set from the tentative element set used in formulating the tentative mathematical model, as the tentative element set.

5. The information processing apparatus according to claim 4,
wherein the predetermined condition is a condition that the number of consecutive times the tentative mathematical model is determined to be feasible is greater than or equal to a threshold value.

6. An information processing method executed by a processor included in an information processing apparatus, the method comprising:
selecting an excluded element set that is a subset of a tentative element set, from the tentative element set that is at least a part of a solution target element set which is an element set constituting an optimization problem as a solution target and which is composed of a plurality of elements;
determining whether or not a tentative mathematical model that is a mathematical model in which an element set excluding the excluded element set from the tentative element set and a constraint condition are formulated, is feasible;
extracting, in a case where the tentative mathematical model is determined to be infeasible, a list of constraint conditions conflicting with each other from the tentative mathematical model;
converting each constraint condition of the extracted list into a name of the constraint condition; and
outputting the name of the constraint condition obtained by conversion.

7. A non-transitory computer-readable storage medium storing an information processing program executable by a processor included in an information processing apparatus to execute a process comprising:
selecting an excluded element set that is a subset of a tentative element set, from the tentative element set that is at least a part of a solution target element set which is an element set constituting an optimization problem as a solution target and which is composed of a plurality of elements;
determining whether or not a tentative mathematical model that is a mathematical model in which an element set excluding the excluded element set from the tentative element set and a constraint condition are formulated, is feasible;
extracting, in a case where the tentative mathematical model is determined to be infeasible, a list of constraint conditions conflicting with each other from the tentative mathematical model;
converting each constraint condition of the extracted list into a name of the constraint condition; and
outputting the name of the constraint condition obtained by conversion.
